(19) United States
(12) Patent Application Publication
(10) Pub. No.: US 2022/0258608 A1
(43) Pub. Date: Aug. 18, 2022

(54) CONTROL DEVICE FOR A MOTOR VEHICLE

(71) Applicants: NOVARES FRANCE, Clamart (FR); TANGI0 LIMITED, London (GB)

(72) Inventors: François BOLLIER, Nice (FR); Christophe CAZES, VERSAILLES (FR); Frédérick REICHHELD, Menton (FR); Ilan Johan Eduardo Olivarez CORREA, London (GB); Ming KONG, London (GB); Liucheng GUO, London (GB)

(21) Appl. No.: 17/618,628

(22) PCT Filed: Jun. 10, 2020
(86) PCT No.: PCT/FR2020/050988

§ 371 Date: Dec. 13, 2021

(30) Foreign Application Priority Data
Jun. 24, 2019 (FR) FR19/06809

(51) Int. Cl. B60K 37/06; B60R 16/023; E05B 81/76; G06F 3/01; H03K 17/96

(52) U.S. Cl. CPC B60K 37/06; B60R 16/0231; E05B 81/77; G06F 3/016; H03K 17/962; H03K 2217/96015; B60K 2370/782; B60K 2370/794; B60K 2370/774; B60K 2370/788; B60K 2370/1446; B60K 2370/158

(57) ABSTRACT

A passenger compartment equipment for controlling a function of a motor vehicle includes a body that includes a control region having sensors which are configured to generate an electrical signal in response to an action such as a force or pressure exerted on at least one of the sensors and which can be connected to an electronic control unit (ECU) of the vehicle. The equipment further includes a haptic feedback module that can be connected to the ECU adjacent to the control region and to the caps covering the sensors and the haptic feedback module. The electrical signal generated by the sensors is transmitted to the ECU for analysis and for conversion into a command of a function of the vehicle and of the haptic feedback module.

### TECHNICAL FIELD

The present disclosure concerns a passenger compartment equipment of a motor vehicle intended to control one or several function(s) of said vehicle.

### BACKGROUND

The passenger compartment of a motor vehicle constitutes for users—driver and possible passengers—a place to live and interact with controls that allow monitoring functions of the vehicle; these functions are of a very diverse nature and concern the actual operation of the vehicle such as the parking brake, the direction indicators, and also concern the well-being of the users such as the infotainment system, the air-conditioning system.

The controls that are typically found inside a vehicle and which constitute the interface for monitoring the functions of a vehicle include in particular:
push buttons, for example, for controlling the locking of a vehicle,
rotary knobs, for example, for controlling the temperature setting of the air-conditioning system;
tilting buttons, for example, for controlling the mechanism for opening/closing the windows
trigger, example, for controlling the door opening mechanism
cursors, for example, for controlling the temperature setting of the air conditioning system

The vehicle passenger compartment is therefore equipped with a multitude of control members. These control members—buttons, cursors, etc.—are of the mechanical or electromechanical type. As such, these control members are, on the one hand, relatively expensive and, on the other hand, have significant installation constraints in the passenger compartment of the vehicle since they could only be positioned at locations that allow accommodating their mechanisms. This last constraint therefore greatly reduces the freedom of design of the passenger compartment since the location of these members is dictated not according to ergonomic considerations but according to mechanical constraints that might be in contradiction with ergonomic considerations.

Furthermore, the passenger compartment of the vehicles is, in addition, enriched by digital screens which may be disseminated in the passenger compartment, these screens being associated with monitoring interfaces for driving vehicular functions. These screens may be driven by interfaces such as touchpads or rotary knobs. Given the large deployment of digital screens that are found not only in the dashboard but also on the backs of seats, on the door cassettes, on the A, B or C pillars, the control of the screens poses certain problems. These screens may be small and beyond the reach of direct access by users.

### SUMMARY

In this technical context, an aim of the disclosure is to improve the interface for controlling vehicular functions in order to provide a more ergonomic and less expensive passenger compartment.

The disclosure concerns a passenger compartment equipment for controlling a function of a motor vehicle, characterized in that the equipment comprises a body in which is formed a control area comprising sensors configured to generate an electrical signal in response to an action such as a force or a pressure exerted on at least one of the sensors and which could be connected to an Electronic Control Unit (ECU) of the vehicle, a haptic feedback module which may be connected to the ECU, adjacent to the control area and cowling elements covering said sensors and said haptic feedback module, the electrical signal generated by the sensors being transmitted to the ECU to be analyzed therein and converted into a control of a function of the vehicle and of the haptic feedback module.

In addition, the disclosure may comprise, separated or in combination, the following arrangements:
the sensors are made of a conductive material which makes it possible to measure a variation in electrical signals associated to micro-deformations of this material during contact or pressure thereon.
the sensors act in capacitive mode or in resistive mode,
the body comprises a lower shell and cowling means between which the sensors and the haptic feedback module are disposed.
the cowling means comprise an upper shell which extends over the entirety of the lower shell,
the sensors are produced by molding with the upper shell,
the cowling means comprise a flexible skin complementary with an upper shell which extends partially over the lower shell.
the sensor has at least one planar portion on which a user's finger could rest.
at least one sensor forms a protuberance at the surface of the control area on which a users finger could rest.
the equipment belongs to the group comprising a door handle, a dashboard element, a center console, an armrest, a steering wheel, an A, B or C pillar, a door cassette, a headrest, a seat element.

The disclosure also concerns a motor vehicle comprising passenger compartment equipment for controlling a function according to any of the aforementioned features.

### BRIEF DESCRIPTION OF THE DRAWINGS

For a better understanding thereof, the disclosure is described with reference to the appended drawings representing as a non-limiting example an embodiment of a passenger compartment equipment which is a grab handle for the purposes of illustration of the disclosure.

FIG. 1 is a perspective view of a passenger compartment equipment which is a side grab handle;

FIG. 2 is an exploded perspective view of the equipment;

FIG. 3 shows a perspective top view of the equipment on which components have been omitted to let reveal the inner structure of the equipment;

FIG. 4 shows a perspective top view of the equipment on which components have been omitted to let reveal the inner structure of the equipment;

FIG. 5 shows a perspective end view of the equipment on which components have been omitted to let reveal the inner structure of the equipment;

FIG. 6 shows a perspective view of the equipment in top view on which components have been omitted to let reveal the inner structure of the equipment;

FIG. 7 shows a perspective view of the equipment on which components have been omitted to let reveal the inner structure of the equipment;

FIG. 8 is a view of the equipment used to monitor a screen;

FIG. 9 is a view of the equipment used to monitor the raising and the lowering of a window;

FIG. 10 is a view of the equipment used to monitor the unlocking of a door;

FIG. 11 illustrates the actions performed on the equipment by a user to monitor a screen;

FIG. 12 illustrates the actions performed on the equipment by a user to monitor the raising and the lowering of a window; and

FIG. 13 illustrates the actions performed on the equipment by a user to monitor the unlocking of a door.

### DETAILED DESCRIPTION OF THE DRAWINGS

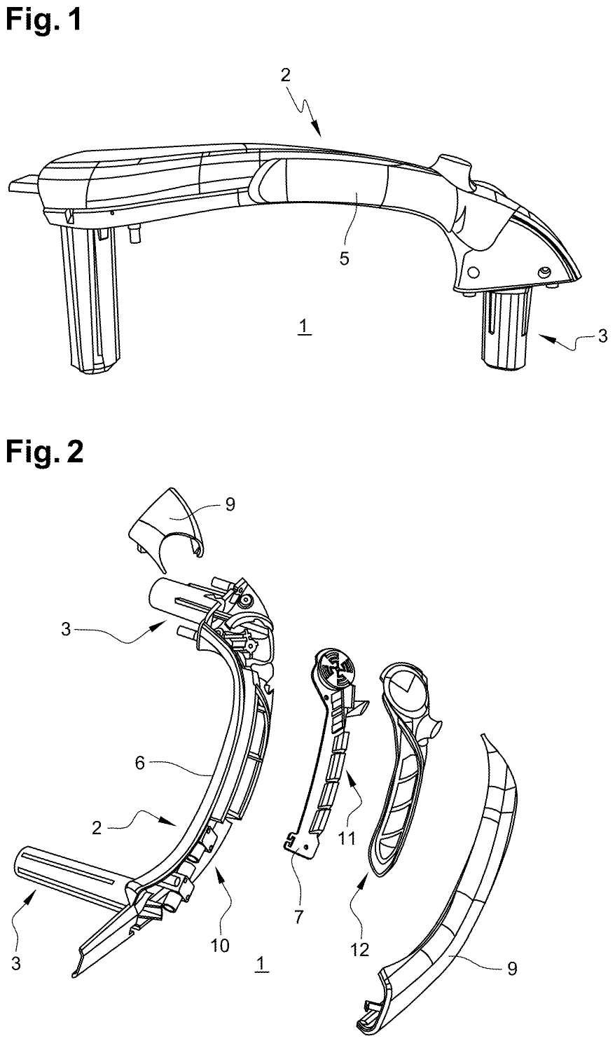

FIGS. 1 to 7 show a passenger compartment equipment of a vehicle according to the disclosure. In this embodiment of the disclosure, the equipment is an internal handle 1 which is conventionally found in a door cassette of a vehicle.

In the present case, the internal handle 1 has a central body 2 enabling gripping by a user and two pins 3 enabling fastening of the handle in a door cassette.

As shown in this figure, the handle has a control area 5 for several functions of the vehicle which constitutes a characteristic of the disclosure and which will now be more particularly described.

FIG. 2 shows in exploded perspective the handle according to the disclosure.

As shown in this figure, the body 2 comprises a lower shell 6 which is preferably made of an injected plastic material, the fastening pins 3 being molded with the lower shell 6.

The lower shell 6 is provided with housings which accommodate a printed circuit 7 and a haptic feedback module 10.

The printed circuit 7 embeds a series of sensors 11. The sensors 11 includes a conductive material which has, at least partially, a surface configured to generate an electrical signal in response to a displacement of a conductive object, in particular a finger of a user therethrough.

The conductive material that constitutes the sensors 11 is flexible and may be, for example, a rubber charged with conductive particles. The sensors 11 may preferably be obtained by molding.

As shown, the sensors 11 are thus molded into specific shapes depending on their application.

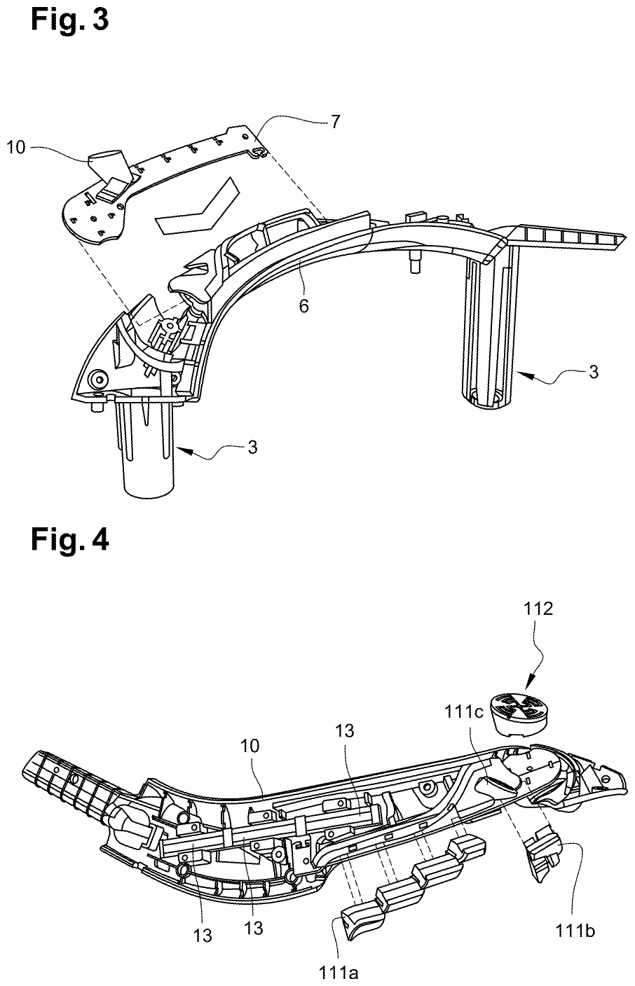

Reference may be made to FIGS. 3 and 4 to appreciate more precisely the sensors 11, their types and their positions.

In the embodiment of the disclosure that could be seen more particularly in FIG. 4, the printed circuit 7 receives:
four sensors 111a which are disposed in series along an anterior generator of the body 2 of the handle so as to be accessible by several fingers of a user when the latter grasps the handle. These are four substantially parallelepipedal elements, the outer face of which (that is to say the face opposite to the face for fastening on the printed circuit) has a geometry in the form of a cylinder portion;
a sensor 111b which is disposed on the posterior face of the body 2 of the handle so as to be accessible to a user's index finger when the latter grasps the handle. The sensor 111b has an end in the form of a beak, that is to say an end whose section tapers.
a sensor 111c which is disposed on the front face of the body 2 of the handle so as to be accessible to a user's thumb when the latter grasps the handle. The sensor 111c also has an end in the form of a beak, the end of which tapers.

Each of the sensors 111b and 111c forms a protuberance at the surface of the body 2. The protrusion formed by the sensors 111b and 111c may be seen, in particular, in FIG. 7.

The handle 1 is also equipped with a sensor 112 which is formed from the same conductive material as that of the sensors 111a, 111b, 111c.

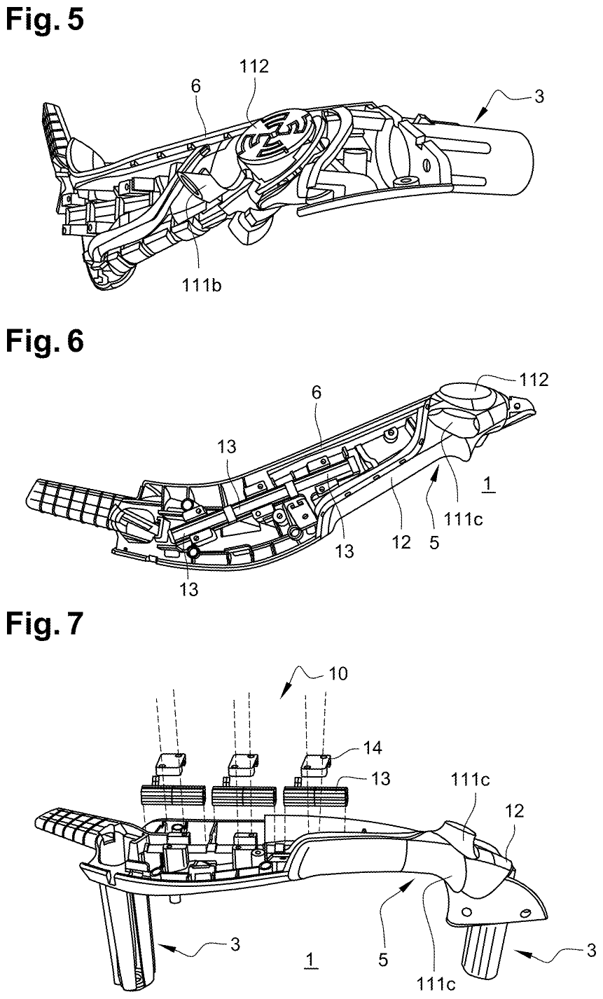

As shown in FIGS. 5 and 6, the sensor 112 may have a disc-like geometry, that is to say it has a planar face which, as will be seen, serves as a support for the user's thumb. In the described example, the sensor 112 is positioned substantially in line with one of the fastening axes 3. The sensor 112 operates at least partially in capacitive mode and to this end may be provided with capacitive tracks 113 which allows it to detect displacement, for example, of fingers at a surface thereof.

In the example embodiment shown in the figures (see for example FIG. 2), the cowling means which encapsulate the sensors 11 and the haptic feedback module 10 are of two types since a flexible skin 12 covers the sensors 11 and an upper shell 9 made of an injected plastic material complements the anterior face of the body 2.

In another embodiment of the disclosure, the upper shell forms the entirety of the visible anterior face of the body 2, that is to say the upper shell covers the sensors 11 and the haptic feedback module 10. The sensors 11 may then be produced by molding with the upper shell.

In the illustrated example, the control area 5 in which the sensors 11 are disposed is therefore sheathed with a flexible skin 12 made of a silicone material. It also should be noted the presence in the lower shell 6 of a haptic feedback module 10. In the illustrated example, the haptic feedback module 10 comprises three actuators 13 which are fastened by staples 14 on the lower shell 6.

The upper shell 9 is secured on the lower shell 6. The upper shell 9 which, in the present case, is split into two sub-elements does not cover the series of sensors 11; in turn, the sensors 11 are covered with a flexible silicone skin 12. The face visible for the user of the internal handle 1 is therefore formed by the upper shell 9 (possibly in two portions) of a plastic material and by the skin 12 of silicone which materializes the location of the sensors 11 and therefore the control area 5.

The set of sensors 11 and the haptic feedback module 10 are connected to an Electronic Control Unit (ECU) of the vehicle which, in a conventional manner, comprises a processor, ROM, EPROM, EEPROM and RAM memories and an Input/Output interface. The ECU embeds one or several software.

The sensors 11 are connected to an ECU, for example, by a CAN bus of the vehicle so that the measured data (variations in resistance of the sensors 11 in response to micro-deformations) are transmitted to one of the ECUs.

In the case of the present disclosure, the ECU embeds specific software which processes the data coming from the sensors 11 and, depending on their features, determines what action is to be performed in the vehicle.

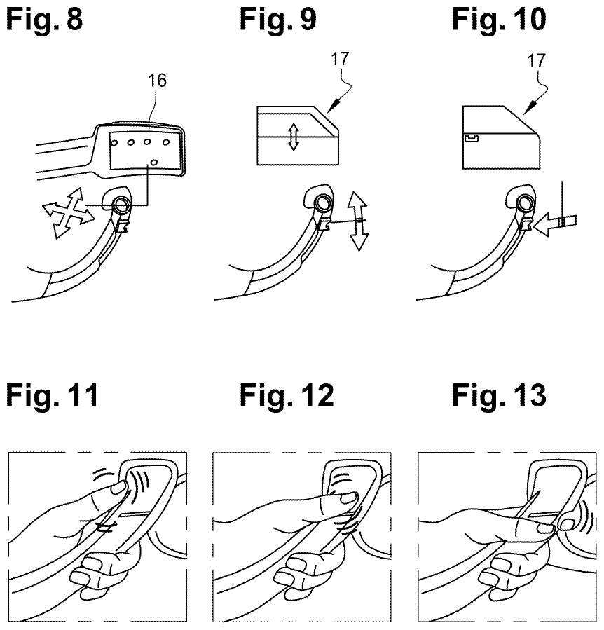

FIGS. 8 to 10 show three functions that could be controlled by the handle 1 which, it may be recalled, does not have any moving mechanical part except for the haptic feedback module 10:
FIG. 8 shows the control of the navigation in a small screen 16 which is integrated in the door cassette;
FIG. 9 shows the control of the raising and the lowering of a window of the door 17;
FIG. 10 shows the control for unlocking the door 17. These three very distinct functions are monitored by the user from the unique control area 5.

FIG. 11 shows how a user controls the screen 16. For this purpose, the user grips the body 2 of the handle and places his thumb at the end of the handle above the sensor 112; the pressure that the user's four fingers exert on the body 2 is detected by the sensors 111a and the movement of the user's thumb is detected by the sensor 112. The electrical signals detected by the sensors 111a and 112 are transmitted to the ECU. According to the analysis made at the level of the ECU, an action is transmitted to the screen 16 (for example to displace a pointer on the screen 16 and select a menu displayed on the screen 16) and an action is transmitted to the haptic feedback module 10 so that it emits a vibration, for example, when selecting a menu on the screen 16.

FIG. 12 shows how a user controls the raising and lowering of a window. For this purpose, the user clasps the body of the handle and places his thumb at the end of the handle on the sensor 111c which forms a protuberance; the pressure that the user's four fingers exert on the body 2 is detected by the sensors 111a and the pressure of the thumb which, in the event where the user seeks to raise or lower a window, is typically a continuous and moderate pressure, is detected by the sensor 111c. The electrical signals created by the deformation of the sensors 111a and 111c are transmitted to the ECU. According to the analysis made at the level of the ECU, an action is transmitted to the engine housed in the door cassette which causes the raising and lowering of the window and an action is transmitted to the haptic module 10 so that the latter emits a vibration during the raising or lowering of the window which evokes for the user the consideration of his request and the execution of this control.

FIG. 13 shows how a user controls the unlocking of the door 17. For this purpose, the user clasps the body 2 of the handle and places his index finger at the end of the handle on the sensor 111b which forms a protuberance; the pressure that the user's four fingers exert on the body 2 is detected by the sensors 111a and the pressure of the index finger which, in the event where a user seeks to unlock a door is typically intense and brief, is detected by the sensor 111c. The electrical signals created by the deformation of sensors 111a and 111c are transmitted to the ECU. According to the analysis made at the level of the ECU, an action is transmitted to the motor which causes the unlocking of the door and an action is transmitted to the haptic module 10 so that it emits a vibration for example intense and brief which evokes to the user, for example, a linkage mechanism that starts to move.

The passenger compartment equipment according to the disclosure allows movements in an intuitive manner for the user and allows easy learning of the use of this control equipment.

These illustrated three functions are not limiting of the disclosure; the equipment being able to control all possible functions present in a passenger compartment and controllable and monitorable by the user from a unique control area 5.

The disclosure thus provides a passenger compartment equipment which is devoid of any mechanism and which makes it possible to control vehicular functions thanks to sensors on which a user exerts manual actions on a unique equipment which imitate the manual actions conventionally performed by the user on a plurality of mechanical control members. This makes it possible not to destabilize the user by offering him to perform actions that are familiar and intuitive to him while freeing him from the constraints specific to conventional mechanisms (costs and complexity of positioning and integration into a vehicle passenger compartment).

The disclosure is described more particularly with reference to a handle but could for example be applied to a steering wheel in which sensors are disposed for controlling an audible warning device or direction indicators.

1. A passenger compartment equipment for controlling a function of a motor vehicle, the passenger compartment equipment comprises: a body in which is formed a control area comprising sensors configured to generate an electrical signal in response to an action such as a force or a pressure exerted on at least one of the sensors and which may be connected to an Electronic Control Unit (ECU) of the vehicle, a haptic feedback module connectable to the ECU, adjacent to the control area and cowling elements covering said sensors and said haptic feedback module, the electrical signal generated by the sensors being transmitted to the ECU to be analyzed therein and converted into a control of a function of the vehicle and of the haptic feedback module.

2. The passenger compartment equipment according to claim 1, wherein the sensors comprise a conductive material which makes it possible to measure a variation in electrical signals associated with micro-deformations of this material during a contact or a pressure thereon.

3. The passenger compartment equipment according to claim 1, wherein the sensors act in capacitive mode or in resistive mode.

4. The passenger compartment equipment according to claim 1, wherein the body comprises a lower shell and cowling means between which the sensors and the haptic feedback module are disposed.

5. The passenger compartment equipment according to claim 4, wherein the cowling means comprise an upper shell which extends over the entirety of the lower shell.

6. The passenger compartment equipment according to claim 5, wherein the sensors are produced by molding with the upper shell.

7. The passenger compartment equipment according to claim 4, wherein the cowling means comprise a flexible skin complementary to an upper shell which partially extends over the lower shell.

8. The passenger compartment equipment according to claim 1, wherein the sensor has at least one planar portion on which a finger of a user could rest.

9. The equipment according to claim 1, wherein at least one sensor forms a protuberance at the surface of the control area on which a finger of a user could rest.

10. The passenger compartment equipment according to claim 1, wherein the equipment belongs to the group consisting of a door handle, a dashboard element, a central console, an armrest, a steering wheel, an A, B, or C pillar, a door cassette, a headrest, and a seat element.

11. A motor vehicle comprising a passenger compartment equipment for controlling a function according to claim 1.
